(19) United States
(12) Patent Application Publication
(10) Pub. No.: US 2009/0236221 A1
(43) Pub. Date: Sep. 24, 2009

(54) MAGNETRON SPUTTERING TARGET STRUCTURE AND APPARATUS HAVING THE SAME

(76) Inventors: Wenyu ZHANG, Beijing (CN); Xin ZHAO, Beijing (CN)

Correspondence Address: LADAS & PARRY LLP, 224 SOUTH MICHIGAN AVENUE, SUITE 1600, CHICAGO, IL, 60604, US

(21) Appl. No.: 12/267,709

(22) Filed: Nov. 10, 2008

(30) Foreign Application Priority Data
Mar. 21, 2008 (CN) 200820079516.X

(51) Int. Cl. C23C 14/35

(52) U.S. Cl. 204/298.12

(57) ABSTRACT

An embodiment of the invention provides a magnetron sputtering target structure, comprising a transmission device, at least two transmission shafts, and a plurality of magnetic bars. The transmission device winds around the transmission shafts and thus forms a transmission structure, and the magnetic bars are disposed in parallel on the transmission device.

### FIELD OF THE PRESENT INVENTION

The present invention relates a magnetron sputtering target structure and an apparatus having the same.

### BACKGROUND OF THE PRESENT INVENTION

Magnetron sputtering technology is a conventional technology employed in coating technology, the basic operating principle of which is to impact a surface of a target material with ions of high energy in plasmas produced with a radio frequency power source or a direct current power source and deposit particles escaping from the surface of the target material onto a surface of a substrate, so as to form a film on the surface of the substrate.

A conventional magnetron sputtering target structure employed in a magnetron sputtering coating apparatus is generally designed as a fixed type. As show in FIG. 1, magnetic bars 11 are fixed onto magnetic bar holding rods 12 in a fixed state. In such a structure, N-pole magnets and S-pole magnets of the magnetic bars produce non-uniform magnetic field, which in turn causes non-uniform distribution of electron concentration, and therefore, the consumption area in a target material 13 is limited within a narrow region, as shown in FIG. 2. After a long-time operation, a very deep etching groove is formed in the consumption area of the target material 13, which affects the stable working of magnetron sputtering target structure and the effect of sputtering, and moreover, the target material is wasted.

In order to improve the uniformity of electron concentration, a reciprocating magnetron sputtering target structure is suggested in a conventional design. As shown in FIGS. 3A, 3B and 3C, magnetic bars 18 are fixed onto a magnetic bar fixing board 14 placed on a nut 15 and reciprocate through the rotating of a screw rod 17 provided on a screw fixing platen 16. However, the travel of the reciprocating movement of the magnetic bars 18 is limited by space and thus is insufficient. Therefore, the magnetic field distribution uniformity can not be substantially improved, and the aims of uniformly consuming target materials and prolonging service life of target materials can not be achieved.

### SUMMARY OF THE INVENTION

An embodiment of the invention provides a magnetron sputtering target structure, comprising a transmission device, at least two transmission shafts, and a plurality of magnetic bars. The transmission device winds around the transmission shafts and thus forms a transmission structure, and the magnetic bars are disposed in parallel on the transmission device.

Another embodiment of the invention provides a magnetron sputtering target apparatus comprising a magnetron sputtering target structure and a target material. The magnetron sputtering target structure comprises a transmission device, at least two transmission shafts, and a plurality of magnetic bars, the transmission device winds around the transmission shafts and thus forms a transmission structure, and the magnetic bars are disposed in parallel on the transmission device. The target material is located outside of the transmission structure.

With embodiments of the invention, the magnets can be moved regularly by using a transmission device, and a parallel and uniform magnetic field can be obtained, which therefore enables a very uniform consumption of the target material and avoids the problem of partial overconsumption, thus improves the utilization rate and prolongs the service lifetime of target materials.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from the following detailed description.

### DESCRIPTION OF THE DRAWINGS

The present invention will become more fully understood from the detailed description given hereinafter and the accompanying drawings which are given by way of illustration only, and thus are not limitative of the present invention and wherein:

FIG. 1 is a plan schematic view of a conventional fixed type magnetron sputtering target structure;

FIG. 2 is a schematic diagram illustrating the relationship between electron distribution and target material consumption when employing the structure shown in FIG. 1;

FIG. 3A is a plan schematic view illustrating a conventional reciprocating type magnetron sputtering target structure;

FIG. 3B is a longitudinal section view taken along line A-A′ of the reciprocating type magnetron sputtering target structure;

FIG. 3C is a transverse section view taken along line B-B′ of the reciprocating type magnetron sputtering target structure;

FIG. 4A is a plan schematic view illustrating the magnetron sputtering target device according to a first embodiment of the invention;

FIG. 4B is a transverse section view taken along line C-C′ of the magnetron sputtering target structure of FIG. 4A; and

FIG. 5 is a schematic view illustrating a second embodiment of the present invention.

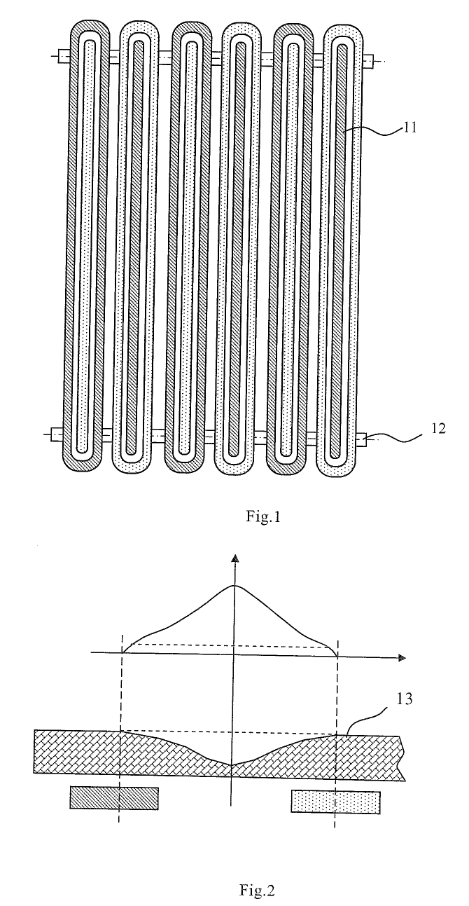

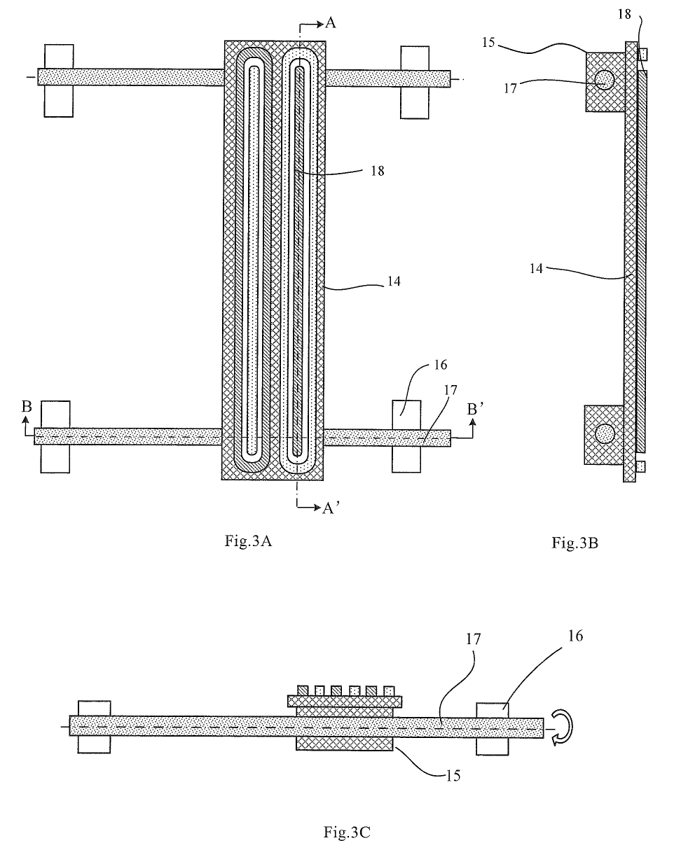

### DETAILED DESCRIPTION OF THE PREFERRED EMBODIMENTS

### Embodiment 1

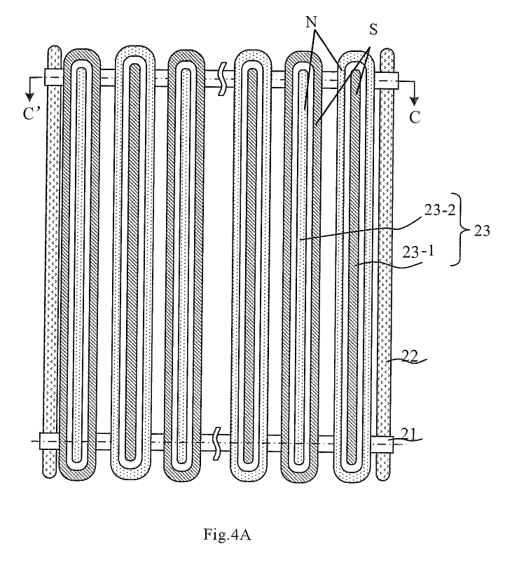

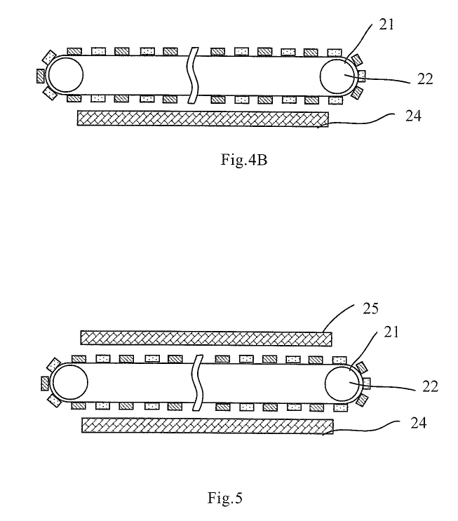

As shown in FIGS. 4A and 4B, a magnetron sputtering target apparatus comprises a magnetron sputtering target structure and a target material 24 located outside of the magnetron sputtering target structure. The magnetron sputtering target structure comprises a plurality of magnetic bars 23, two rotating shafts 22, and a transmission device 21 which winds around the rotating shafts 22 to form a transmission structure. The magnetic bars 23 comprise positive magnetic bars 23-1 and negative magnetic bars 23-2, which are disposed on the transmission device 21 alternatively and in parallel. In driving the transmission device 21 to rotate with the rotating shaft 22, the magnetic bars 23 move regularly together with the transmission device 21.

The magnetic bars 23 arranged on the transmission device 21 is constructed so that the N-pole magnet of the positive magnetic bars 23-1 is of a long ring shape, and the S-pole magnet of the positive magnetic bars 23-1 is of a strip shape and is located within the long ring-shaped N-pole magnet, and the S-pole magnet of the negative magnetic bars 23-2 is of a long ring shape, and the N-pole magnet of the negative magnetic bars 23-2 is of a strip shape and is located within the long ring-shaped S-pole magnet.

Specifically, the transmission device may be a chain transmission device. Chain transmission is a kind of engagement transmission in which chain is used for flexible traction between two sprockets on the two parallel rotating shafts 22 to transfer motion and power. Since the chain transmission has no elastic sliding and slipping, it can keep an accurate average transmission ratio as well as a high transmission efficiency; since it is not necessary to tighten the chain to a great extent, the needed shaft compressing force is small; transmission power is high and overload capacity is strong; chain transmission works well at a low-speed and under a heavy burden; and it is also applicable in a harsh environment, such as dusty, oil contamination, corrosive, and high-strength situations. Specifically, the chain used in chain transmission device may be driving chains, lifting chains and traction chains.

In addition, the transmission device 21 may also be a belt transmission device. The belt transmission device is advantageous due to its high elasticity, cushioning, vibration absorption, stable transmission, no lubrication and cleaning required, and low noise, and the like. Once overloaded, a transmission belt slips on the rotating shaft 22, thus preventing damage to the other parts and acting as a safety protection means. Moreover, the belt transmission device is also applicable for the case of a relatively long centre distance and advantageous due to its simple structure, low cost, convenience in assemble, and disassemble. Specifically, the belt transmission device may be a friction type belt transmission device or an engagement type belt transmission device.

The magnetron sputtering target device according to this embodiment differs from not only the conventional fixed type magnetron sputtering target device but also the conventional reciprocating magnetron sputtering target device. The magnetron sputtering target device according to the invention can make the magnetic bars 23 move regularly together with rotate of the transmission device 21, and for example, it may drive the target strips 23 to rotate in a uniform speed by the transmission device 21, thus generates a uniform magnetic field, improves the consumption area of the target materials surface substantially, increases the occupation ratio, prolongs the service life of the target materials, and also improves the effect of sputtering coating.

### Embodiment 2

As shown in FIG. 5, this embodiment differs from embodiment 1 in that an additional target material 25 is disposed on another side of the magnetron sputtering target structure. In such a manner, the consumption area achieves the same substantial improvement, and this embodiment can farther increase the working efficiency of magnetron sputtering coating device, besides improving the utility ratio and prolonging the service life of target materials.

The embodiments of the invention being thus described, it will be obvious that the same may be varied in many ways. Such variations are not to be regarded as a departure from the spirit and scope of the invention, and all such modifications as would be obvious to those skilled in the art are intended to be comprised within the scope of the following claims.

What is claimed is:

1. A magnetron sputtering target structure comprising a transmission device, at least two transmission shafts, and a plurality of magnetic bars, wherein said transmission device winds around said transmission shafts and thus forms a transmission structure, and said magnetic bars are disposed in parallel on said transmission device.

2. The magnetron sputtering target structure according to claim 1, wherein each of the said magnetic bars comprises an N-pole magnet and a S-pole magnet, and said N-pole magnet and S-pole magnet of the plurality of magnetic bars are disposed on said transmission device alternatively and in parallel.

3. The magnetron sputtering target structure according to claim 1, wherein said magnetic bars comprise positive magnetic bars and negative magnetic bars, and an N-pole magnet of the positive magnetic bars is of a long ring shape and a S-pole magnet of the positive magnetic bars is of a strip shape and located within said long ring-shape, while a S-pole magnets of negative magnetic bars is of a long ring shape and an N-pole magnets of negative magnetic bars is of a strip shape and located within said long ring shape.

4. The magnetron sputtering target structure according to claim 1, wherein said magnetic bars is formed of a material selected from the group consisting of a permanent magnet and an electric magnet.

5. The magnetron sputtering target structure according to claim 1, wherein said transmission device is a belt transmission device.

6. The magnetron sputtering target structure according to claim 5, wherein said belt transmission device is selected from the group consisting of a friction-type belt transmission device and an engagement-type belt transmission device.

7. The magnetron sputtering target structure according to claim 1, wherein said transmission device is a chain transmission device.

8. The magnetron sputtering target structure according to claim 7, wherein a chain used in said chain transmission device is selected from the group consisting of a driving chain, a lifting chain, and a traction chain.

9. A magnetron sputtering target apparatus comprising a magnetron sputtering target structure and a target material, wherein
the magnetron sputtering target structure comprises a transmission device, at least two transmission shafts, and a plurality of magnetic bars, said transmission device winds around said transmission shafts and thus forms a transmission structure, and said magnetic bars are disposed in parallel on said transmission device; and
the target material is located outside of said transmission structure.

10. The magnetron sputtering target apparatus according to claim 9, wherein each of the said magnetic bars comprises an N-pole magnet and a S-pole magnet, and said N-pole magnet and S-pole magnet of the plurality of magnetic bars are disposed on said transmission device alternatively and in parallel.

11. The magnetron sputtering target apparatus according to claim 9, wherein said magnetic bars comprise positive magnetic bars and negative magnetic bars, and an N-pole magnet of the positive magnetic bars is of a long ring shape and a S-pole magnet of the positive magnetic bars is of a strip shape and located within said long ring-shape, while a S-pole magnets of negative magnetic bars is of a long ring shape and an N-pole magnets of negative magnetic bars is of a strip shape and located within said long ring shape.

12. The magnetron sputtering target apparatus according to claim 9, wherein said magnetic bars is formed of a material selected from the group consisting of a permanent magnet and an electric magnet.

13. The magnetron sputtering target apparatus according to claim 9, wherein said transmission device is a belt transmission device.

14. The magnetron sputtering target apparatus according to claim 13, wherein said belt transmission device is selected from the group consisting of a friction-type belt transmission device and an engagement-type belt transmission device.

15. The magnetron sputtering target apparatus according to claim 9, wherein said transmission device is a chain transmission device.

16. The magnetron sputtering target structure according to claim 15, wherein a chain used in said chain transmission device is selected from the group consisting of a driving chain, a lifting chain, and a traction chain.

17. The magnetron sputtering target apparatus according to claim 9, comprising a plurality of target materials located at the upper outside and lower outside of said transmission structure, respectively.
